(19) United States
(12) Patent Application Publication
(10) Pub. No.: US 2022/0359241 A1
(43) Pub. Date: Nov. 10, 2022

(54) SUBSTRATE TREATMENT APPARATUS WITH FLEX-LL FUNCTION, AND SUBSTRATE TRANSFER METHOD

(71) Applicant: ASM IP Holding B.V., Almere (NL)

(72) Inventor: Yoshiyuki Umeoka, Tokyo (JP)

(21) Appl. No.: 17/736,691

(22) Filed: May 4, 2022

Related U.S. Application Data
(60) Provisional application No. 63/185,997, filed on May 7, 2021.

(51) Int. Cl. H01L 21/67; H01L 21/677; G05B 19/418

(52) U.S. Cl. CPC H01L 21/67201; H01L 21/67167; H01L 21/67742; G05B 19/41815; G05B 2219/2602; G05B 2219/45032

(57) ABSTRACT

Examples of a substrate treatment apparatus include a plurality of load ports, a front-end module adjacent to the plurality of load ports, a plurality of load lock chambers adjacent to the front-end module, the plurality of load lock chambers include a plurality of wafer housing slots, a wafer handling chamber adjacent to the plurality of load lock chambers, a first wafer transfer device in the front-end module, a second wafer transfer device in the wafer handling chamber, and a controller including a processor and a memory configured to cause the processor to execute a program stored in the memory, or including a dedicated circuitry, to issue a command to a wafer moving device to move a wafer between the plurality of load lock chambers when predetermined wafer transfer conditions are satisfied.

### CROSS-REFERENCE TO RELATED APPLICATIONS

This application claims the benefit of U.S. Provisional Application No. 63/185,997, filed on May 7, 2021, in the United States Patent and Trademark Office, the disclosure of which is incorporated herein in its entirety by reference.

### FIELD

Examples are described which relate to a substrate treatment apparatus and a substrate transfer method.

### BACKGROUND

A substrate treatment apparatus for treating a substrate in a low-pressure space, such as a vacuum, includes a plurality of load lock chambers. The load lock chamber is provided so as to prevent particles, water vapor and contaminants from entering a process chamber. It disturbs an increase in throughput that a wafer cannot be loaded into the load lock chamber despite the presence of an empty slot in the load lock chamber, or a treated wafer cannot be quickly extracted from the load lock chamber.

### SUMMARY

Some examples described herein may address the above-described problems. Some examples described herein may provide a substrate treatment apparatus and a substrate transfer method which can increase the throughput.

In some examples, a substrate treatment apparatus includes a plurality of load ports, a front-end module adjacent to the plurality of load ports, a plurality of load lock chambers adjacent to the front-end module, the plurality of load lock chambers include a plurality of wafer housing slots, a wafer handling chamber adjacent to the plurality of load lock chambers, a first wafer transfer device in the front-end module, a second wafer transfer device in the wafer handling chamber, and a controller including a processor and a memory configured to cause the processor to execute a program stored in the memory, or including a dedicated circuitry, to issue a command to a wafer moving device to move a wafer between the plurality of load lock chambers when predetermined wafer transfer conditions are satisfied.

### BRIEF DESCRIPTION OF THE DRAWINGS

FIG. 1 illustrates a configuration example of a substrate treatment apparatus;

FIG. 2 is a cross-sectional view of the first LLC and its vicinity;

FIG. 3 illustrates an example of an execution flowchart of the FLEX-LL;

FIG. 4 is a flowchart illustrating a specific example of the FLEX-LL;

FIG. 5A illustrates a state in which the wafer transfer conditions are satisfied;

FIG. 5B illustrates that wafers in the second LLC have been moved to the first LLC;

FIG. 5C illustrates that wafers are moved from the load port to the second LLC;

FIG. 6 is a flowchart illustrating another specific example of the FLEX-LL;

FIG. 7A illustrates a state in which the wafer transfer conditions are satisfied;

FIG. 7B illustrates that the wafers have moved to the second LLC;

FIG. 7C illustrates that treated wafers in the first LLC have been returned to the load port;

FIG. 8A illustrates that treated wafers and untreated wafers are housed in the first LLC;

FIG. 8B illustrates that wafers have moved to the second LLC;

FIG. 8C illustrates that the treated wafers have been moved to the load port;

FIG. 9 is a functional block diagram of the controller;

FIG. 10A illustrates a configuration example of the controller;

FIG. 10B illustrates another configuration example of the controller;

FIG. 11 illustrates a configuration example of a wafer moving device;

FIG. 12 illustrates another configuration example of a wafer moving device; and

FIG. 13 shows a method for moving the wafer by the wafer moving device.

### DETAILED DESCRIPTION

A substrate treatment apparatus and a substrate transfer method will be described with reference to the drawings. The same or corresponding constituent components are designated by the same reference numerals, and repeated description thereof is omitted in some cases.

### EMBODIMENT

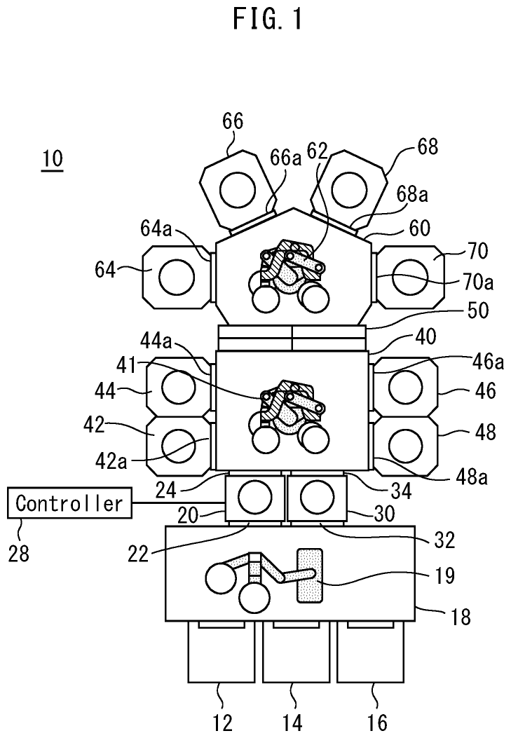

FIG. 1 illustrates a configuration example of a substrate treatment apparatus 10. This substrate treatment apparatus includes a plurality of load ports. In the example of FIG. 1, there are provided load ports 12, 14 and 16. Here, the number of load ports is set at three, but may be two or four or more. A front-end module 18 is provided adjacent to the plurality of load ports 12, 14 and 16. The front-end module 18 includes a Fan Filter Unit (FFU), for example, and is provided so as to transfer a substrate under atmospheric pressure. There is a first wafer transfer device 19 in the front-end module 18. According to one example, the first wafer transfer device 19 is a robot for transferring the wafer. The load ports 12, 14 and 16, the front-end module 18 and the first wafer transfer device 19 are collectively referred to as an Equipment Front End Module (EFEM) or enclosure.

A first load lock chamber (first LLC) 20 and a second load lock chamber (second LLC) 30 are provided adjacent to the front-end module 18. The first LLC 20 and the second LLC 30 are connected to a vacuum device, and can be set to atmospheric pressure or to a vacuum. According to one example, the first LLC 20 and the second LLC 30 are two independent chambers, and the movement of gas from one to the other is prevented. For information, in FIG. 1, two load lock chambers are provided, but three or more load lock chambers may be provided.

A gate valve 22 is provided between the first LLC 20 and the front-end module (FEM) 18. A gate valve 32 is provided between the second LLC 30 and the FEM 18.

A wafer handling chamber (WHC) 40 is provided adjacent to the first LLC 20 and the second LLC 30. There is a second wafer transfer device 41 in the WHC 40. According to one example, the second wafer transfer device 4 is a robot for transferring the wafer. A gate valve 24 is provided between the first LLC 20 and the WHC 40. A gate valve 34 is provided between the second LLC 30 and the WHC 40. Reactor chambers 42, 44, 46 and 48 are adjacent to the WHC 40 via gate valves 42a, 44a, 46a and 48a, respectively.

The WHC 40 is in contact with the WHC 60 via a pass-through chamber 50. According to one example, the pass-through chamber 50 includes an upper pass-through chamber having a gate valve on the WHC 60 side, and a lower pass-through chamber having a gate valve on the WHC 40 side. In other words, in the upper pass-through chamber and also in the lower pass-through chamber, there is one gate valve between the WHC 40 and the WHC 60. Thereby, the pressures of the WHC 40 and the WHC 60 can be made different from each other.

Reactor chambers 64, 66, 68 and 70 are adjacent to the WHC 60 via gate valves 64a, 66a, 68a and 70a, respectively. According to one example, the reactor chamber 42 44, 46 and 48 and the reactor chambers 64, 66, 68 and 70 can be provided as apparatuses for forming an epitaxial growth film on the wafer by single-wafer treatment. According to one example, each of the second wafer transfer device 41 and the third wafer transfer device 62 has perpendicularly arranged two arms. According to another example, the number of arms can be any number.

The transferring of the wafer is controlled by a controller 28. According to one example, the controller 28 controls the first wafer transfer device 19, the second wafer transfer device 41, the third wafer transfer device 62, and each of the gate valves described above, and makes the wafer transfer devices transfer the wafer along a transfer path of the wafer, which is designated by the control job.

The substrate treatment apparatus 10 of FIG. 1 can be configured differently. According to one example, the pass-through chamber 50, WHC 60 and reactor chambers 64, 66, 68 and 70 may be omitted. According to another example, the reactor chamber for single-wafer treatment can be replaced by a Dual Chamber Module (DCM) or a Quad Chamber Module (QCM), or replaced by another batch treatment chamber.

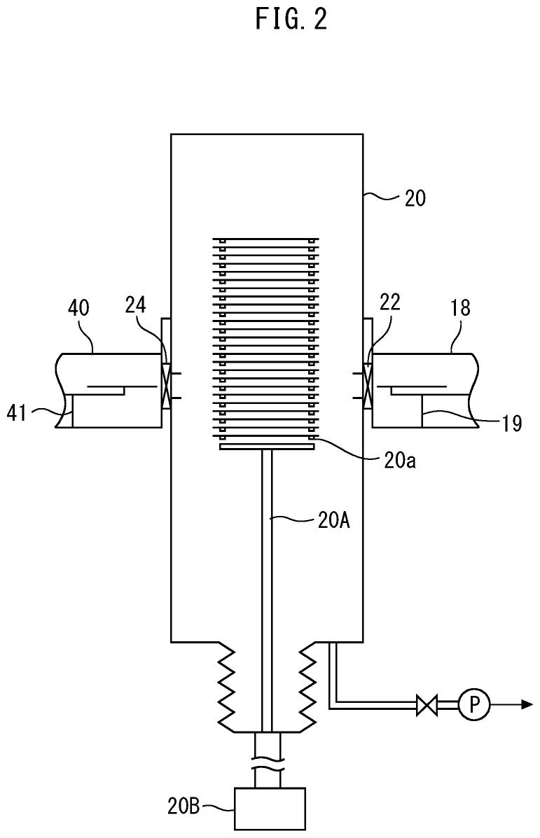

FIG. 2 is a cross-sectional view of the first LLC 20 and its vicinity. The first LLC 20 has a plurality of wafer housing slots. In the example of FIG. 2, 25 wafer housing slots 20a are provided. Accordingly, the first LLC 20 can house a maximum of 25 wafers therein. The 25 wafer housing slots 20a are supported by a shaft 20A. This shaft 20A is structured so as to be capable of moving up and down, for example, by driving of a motor 20B or the like. As the shaft 20A moves up and down, 25 wafer housing slots 20a can also be moved up and down. When a wafer is loaded into the first LLC 20 or a wafer is extracted from the first LLC 20 by use of the first wafer transfer device 19 or the second wafer transfer device 41, a height of an arbitrary wafer housing slot 20a is adjusted to the height of the first wafer transfer device 19 or the second wafer transfer device 41, by the above-described elevation function.

As the second LLC 30, the same configuration as that of the first LLC 20 can be adopted. In this example, each of the first LLC 20 and the second LLC 30 has a plurality of wafer housing slots.

By the control of the controller 28, the transferring of the wafer is executed, for example, as follows.

(1) Wafer transfer from any one of the load ports 12, 14 and 16 to the first LLC 20 or the second LLC 30, by the first wafer transfer device 19.
(2) Wafer transfer from the first LLC 20 or the second LLC 30 to any one of the reactor chambers 42, 44, 46 and 48 or to the pass-through chamber 50, by the second wafer transfer device 41.
(3) Wafer transfer from the pass-through chamber 50 to any one of the reactor chambers 64, 66, 68 and 70, by a third wafer transfer device 62.
(4) Wafer transfer from any one of the reactor chambers 64, 66, 68 and 70 to the pass-through chamber 50, by a third wafer transfer device 62.
(5) Wafer transfer from any one of the reactor chambers 42, 44, 46 and 48, or the pass-through chamber 50, to the first LLC 20 or the second LLC 30, by the second wafer transfer device 41.
(6) Wafer transfer from the first LLC 20 or the second LLC 30 to any one of the load ports 12, 14 and 16, by the first wafer transfer device 19.

According to one example, the wafer is transferred along a wafer transfer path which has been designated by a control job. In addition to the above-described wafer transfer, this substrate treatment apparatus has a function called FLEX-LL. The FLEX-LL is a function of enhancing the throughput through the movement of wafers between the load lock chambers.

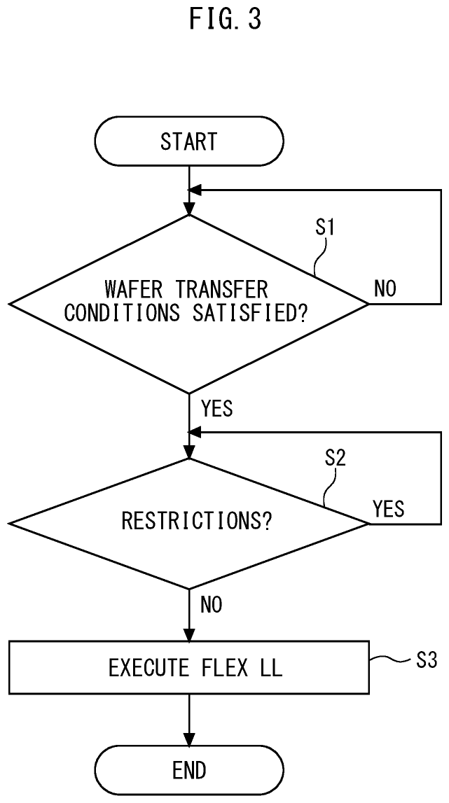

FIG. 3 illustrates an example of an execution flowchart of the FLEX-LL. Firstly, in step S1, it is determined whether conditions for executing the FLEX-LL are satisfied. The execution conditions are predetermined “wafer transfer conditions”. When it is determined that the wafer transfer conditions are satisfied, the process proceeds to step S2. In step S2, it is determined whether or not there is a condition which restricts the execution of FLEX-LL. For example, if the control job prohibits the use of one of the load lock chambers, moving the substrate between the load lock chambers results in infringing an instruction content of the control job, and accordingly the FLEX-LL function is not executed. When it is determined in step S2 that there is no restriction condition, the FLEX-LL is executed in step S3, and the substrate is moved between the load lock chambers. Note that when it is determined whether or not the wafer transfer conditions are satisfied, the restriction condition described above can also be considered.

### Example 1

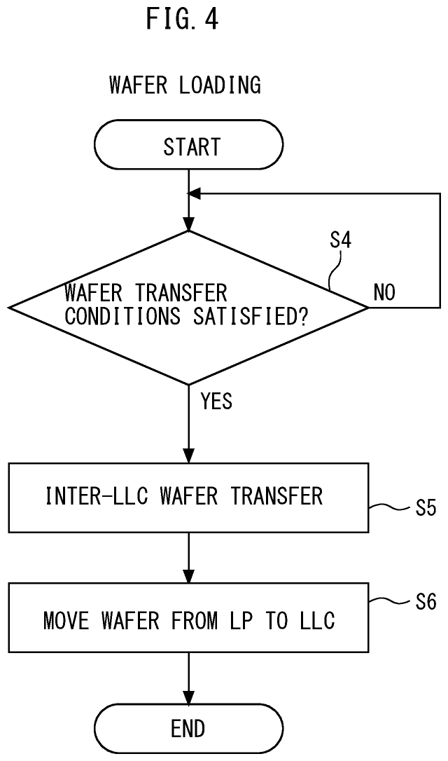

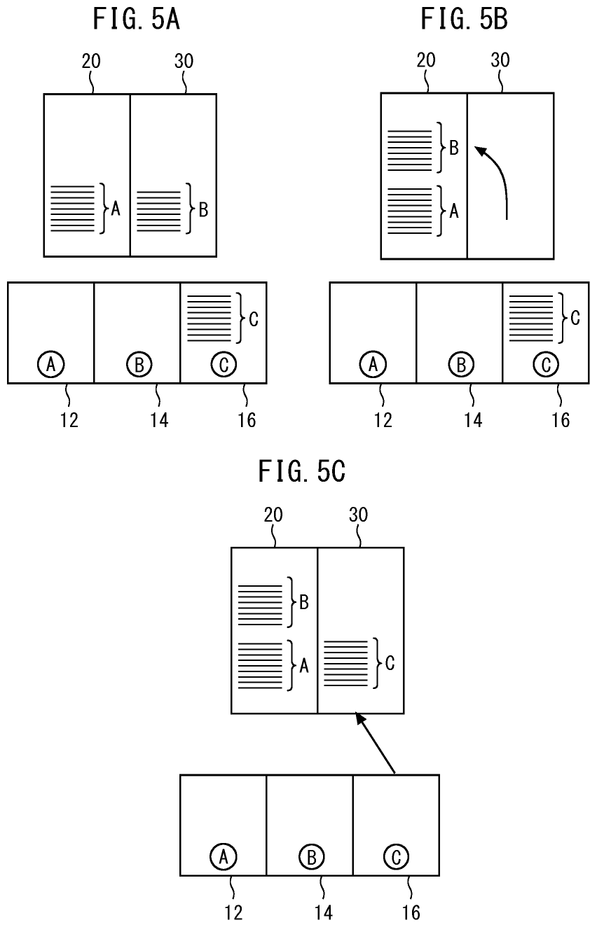

FIGS. 4, 5A, 5B and 5C illustrate a specific example of the FLEX-LL. In this example, firstly, in step S4, it is determined whether wafer transfer conditions are satisfied. The wafer transfer conditions in this example include that there is a wafer of which the treatment is not completed in the first LLC 20 and the second LLC 30, and there is a wafer to be transferred to the first LLC 20 or the second LLC 30, in any one of the plurality of load ports 12, 14 and 16.

FIG. 5A illustrates a state in which the wafer transfer conditions are satisfied. Wafers A are such wafers that are removed from the load port 12, treated in a reactor chamber, and then returned to the load port 12. Wafers B are such wafers that are removed from the load port 14, treated in a reactor chamber, and then returned to the load port 14. Wafers C are such wafers that are removed from the load port 16, treated in a reactor chamber, and then returned to the load port 16. In FIG. 5A, there are nine wafers A before being treated in the reactor chamber, in the first LLC 20, there are eight wafers B before being treated in a reactor chamber, in the second LLC 30, and there are nine wafers C scheduled to be moved to the load lock chamber, in the load port 16. When the controller 28 has determined that the transfer conditions are satisfied, the process proceeds to step S5.

In the step S5, the controller 28 issues a command to a “wafer moving device”, and causes the “wafer moving device” to operate so as to attain a state in which there is no wafer in any one of the first LLC 20 and the second LLC 30.

In FIG. 5B, it is illustrated that eight wafers B in the second LLC 30 have been moved to the first LLC 20. The wafer is moved by the “wafer moving device”. The wafer moving device is, for example, the second wafer transfer device 41. When the wafer is moved between the load locks by the second wafer transfer device 41, the valves 24 and 34 need to be in an open state. According to another example, a wafer transfer device which is different from the wafer transfer device illustrated in FIG. 1 and is specialized in moving wafers between LLCs can be used as the “wafer moving device”. When the processing of the step S5 has been finished, as illustrated in FIG. 5B, the second LLC 30 becomes a state in which no wafer exists there.

According to an example, in the step S5, it is possible to move the wafers housed in the first LLC 20 or the wafers housed in the second LLC 30, the moved wafers having a smaller number than the other wafers. In the example of FIG. 5, nine wafers A are housed in the first LLC 20, and eight wafers B are housed in the second LLC 30; and accordingly, eight wafers B have been moved to the first LLC 20. Thereby, a time period required for the wafer transfer can be shortened as compared with the case where nine wafers A in the first LLC 20 are moved to the second LLC 30. Of course, according to another example, it is also possible to operate the wafer moving device to move the wafers A to the second LLC 30, and to attain a state in which there is no wafer in the first LLC 20.

Next, the process proceeds to step S6. In the step S6, the controller 28 issues a command to the first wafer transfer device 19, and makes the first wafer transfer device move the wafer from any one of the plurality of load ports, to a load lock chamber containing no wafer which is one of the first LLC 20 and the second LLC 30. In the example of FIG. 5C, it is illustrated that nine wafers are moved from the load port 16 to the second LLC 30.

As is illustrated in FIG. 5A, in a state in which untreated wafers exist in both of the first LLC 20 and the second LLC 30, both of the LLCs are in a vacuum state. Therefore, in this state, it is not possible to set the LLC to atmospheric pressure in order to transfer the wafer from the load port to the LLC. In other words, it is not possible to charge the wafer into the LLC in which there is an untreated wafer, from the load port. However, when the above-described FLEX-LL is executed to empty one LLC, the empty LLC can be returned to atmospheric pressure and the wafer can be carried in. When a wafer is newly carried into the LLC, the pressure of the LLC is reduced to a vacuum over a period of time of, for example, about 300 seconds, and the wafer can be quickly subjected to the treatment in the reactor chamber. In this way, the throughput can be enhanced.

The examples of FIGS. 4 and 5 can be summarized in the following way.
The plurality of load ports include a first load port, a second load port and a third load port.
The “wafer transfer conditions” include that there is a wafer in the first LLC 20, which has been transferred from the first load port and of which the treatment is not completed, that there is a wafer in the second LLC 30, which has been transferred from the second load port and of which the treatment is not completed, and that there is a wafer in the third load port, which is to be transferred to the first LLC or the second LLC.

In other words, in the examples of FIGS. 4 and 5, nine wafers A, eight wafers B and nine wafers C form each one group, and result in being transferred in a unit of the group. The number of wafers in each group is not particularly limited. It contributes to simplification of the transfer to proceed the transfer in units of wafers associated with the load port in this way. Because of this, in this example, when the wafers are moved from one of the first LLC and the second LLC to the other, all the wafers (first wafers) which should be returned to the load port 12, all the wafers (second wafers) which should be returned to the load port 14, or all the wafers (third wafers) which should be returned to the load port 16 are moved. Here, any of the wafers A, B and C may be in the first LLC 20, any of the wafers A, B and C may be in the second LLC 30, and any of the wafers may be in any of the load ports, which are waiting to be carried into the LLC.

### Example 2

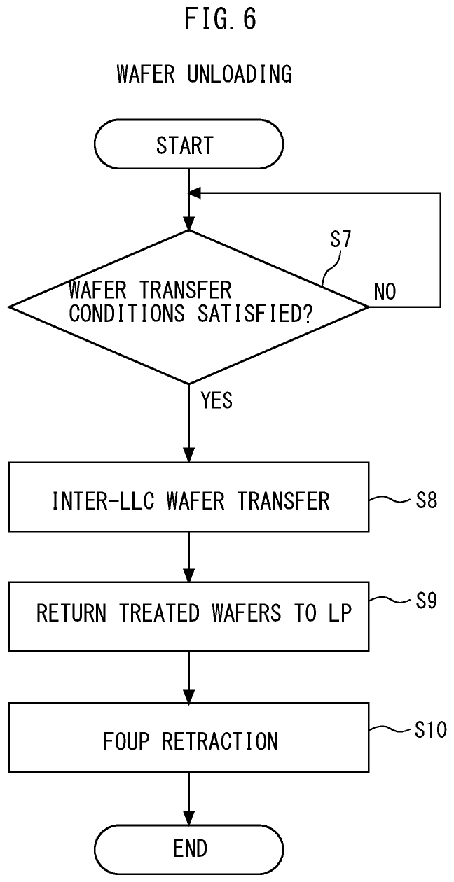

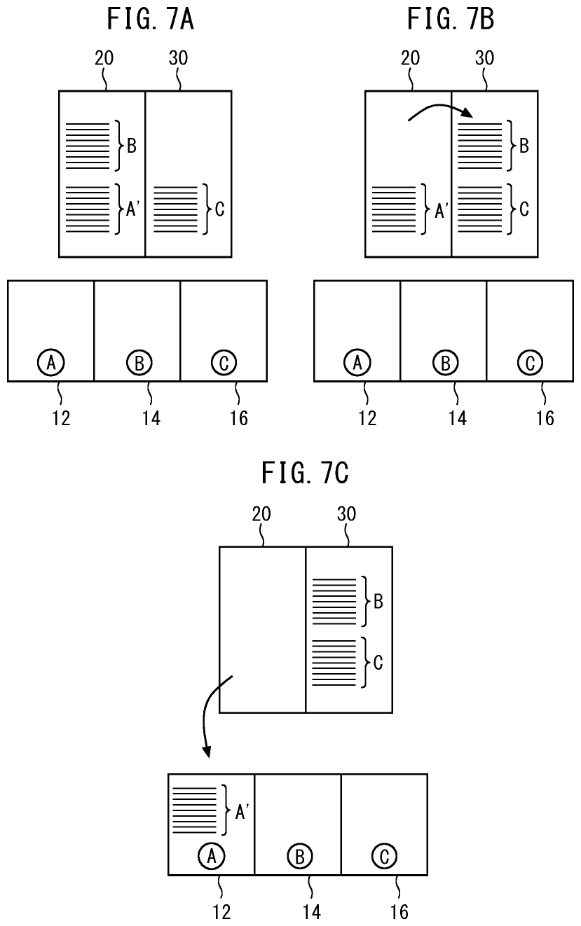

FIGS. 6, 7A, 7B and 7C illustrate another specific example of the FLEX-LL. In this example, firstly, in step S7, it is determined whether wafer transfer conditions are satisfied. The wafer transfer conditions in this example include that a first wafer of which the treatment has been completed and a second wafer of which the treatment is not completed are mixed in the first LLC 20 or the second LLC 30.

FIG. 7A illustrates a state in which the wafer transfer conditions are satisfied, as one example. Specifically, nine wafers A′ which have been treated in a reactor chamber, and nine wafers B before being treated are housed in the first LLC 20. When the controller 28 has determined that the transfer conditions are satisfied, the process proceeds to step S8.

In the step S8, the controller issues a command to the wafer moving device, and causes the wafer moving device to operate so as to attain a state in which there are only the wafers A′ in any one of the first LLC 20 and the second LLC 30. In order to obtain the state in which there are only the wafers A′ in the first LLC 20, nine wafers B in the first LLC 20 are moved to the second LLC 30 by the wafer moving device. The wafer moving device is the second wafer transfer device 41 or the dedicated wafer transfer device, as described above. In FIG. 7B, it is illustrated that the wafers B have moved to the second LLC 30. Thus, the first LLC 20 becomes a state in which only the wafers A′ exist there. In this example, when the controller issues a command to the wafer moving device and the wafer moving device moves the wafers between the load locks, a movement mode can be adopted in which the number of wafers to be moved between the load locks becomes minimal. According to another example, it is also acceptable to move nine wafers C to the first LLC 20, to move nine wafers A′ to the second LLC 30, and thereby to attain a state in which only the wafers A′ exist in the second LLC 30.

Next, the process proceeds to step S9. In the step S9, the wafers A′ which are treated wafers are returned to the load port. In FIG. 7C, it is illustrated that nine wafers A′ in the first LLC 20 have been returned to the load port 12. The first wafer transfer device 19 can be used for moving the wafer.

Next, the process proceeds to step S10. In the step S10, a FOUP housing the wafers A′ is retracted from the load port 12. In this way, by using the FLEX-LL, the treated wafer can be moved from the LLC to the load port at an early stage, accordingly the number of empty slots in the LL can be increased, and the transfer of the treated wafer can be accelerated. It enables charging of a new wafer from the load port into the LLC to move the treated wafer from the LLC to the load port in an early stage.

The examples of FIGS. 6 and 7 can be summarized in the following way.
The plurality of load ports include the first load port and the second load port.
The “wafer transfer conditions” include that the first wafer which has been transferred from the first load port and of which the treatment has been completed and the second wafer which has been transferred from the second load port and of which the treatment is not completed are mixed in the first LLC or the second LLC.
A command which is issued from the controller to the wafer moving device is to operate the wafer moving device and attain a state in which only the first wafer exists in any one of the first LLC and the second LLC.

Specifically, in the example of FIGS. 6 and 7, nine wafers A′, nine wafers B, and nine wafers C each form one group, and result in being transferred in a unit of the group. The number of wafers in each group is not particularly limited. It contributes to simplification of the transfer to proceed the transfer in a unit of the wafer associated with the load port in this way. Here, as long as the untreated wafers are housed in one LLC, any wafer among the wafers A′, B and C may exist in the first LLC 20, or any wafer among the wafers A′, B and C may exist in the second LLC 30. In the second example as well as the first example, various modifications are possible. For example, the treated wafers to be retracted to the load port are determined to be the wafers A′, but the wafers B′, the wafers C′, or a mixture of the wafers A′, B′ and C′ may be determined to be retracted.

### Example 3

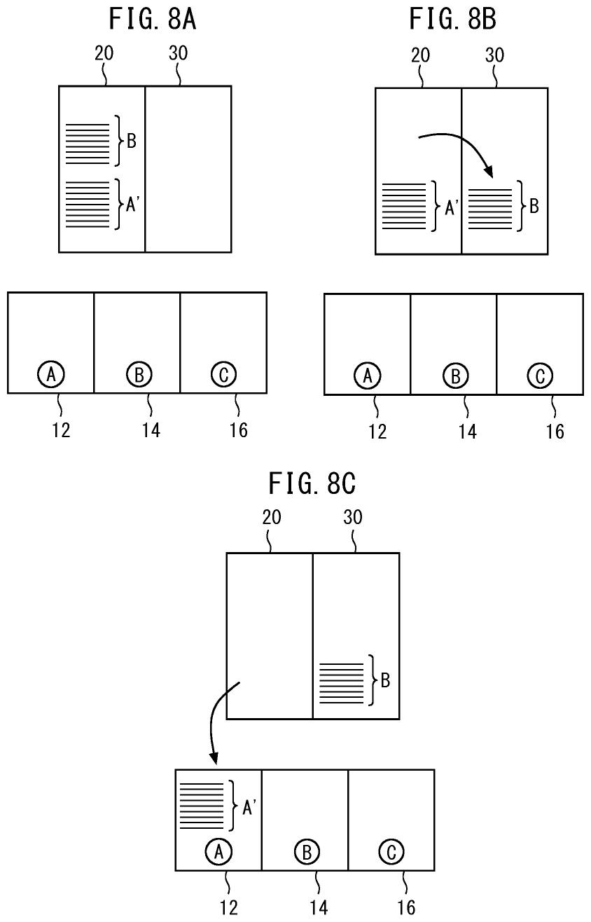

FIGS. 8A, 8B and 8C illustrate another specific example of the FLEX-LL. This example has many similarities to the second example, and the flowchart is the same as that of FIG. 6 referred to in the second example. Hereinafter, differences from the second example will be mainly described. The third example is different from the second example in that there is no wafer in the second LLC 30 at the start of the operation of the FLEX-LL.

Firstly, in step S7, it is checked whether the first wafer of which the treatment has been completed and the second wafer of which the treatment is not completed are mixed in the first LLC 20 or the second LLC 30. In FIG. 8A, it is illustrated that nine treated wafers A′ and nine wafers B before being treated are housed in the first LLC 20. When the controller 28 has determined that the transfer conditions are satisfied, the process proceeds to step S8.

Next, in the step S8, nine wafers B are moved to the second LLC 30. In FIG. 8B, it is illustrated that nine wafers B have moved to the second LLC 30.

Next, in step S9, nine wafers A′ are moved from the first LLC 20 to the load port 12. In FIG. 8C, it is illustrated that the wafers A′ have been moved to the load port 12.

Next, in step S10, the FOUP is carried out from the load port 12. In this way, the wafers A′ can be moved from the LLC to the load port at an early stage by the processing of the FLEX-LL.

It is also acceptable to perform the wafer transfer between LLCs in a mode different from the first to third examples and realize an improvement of the throughput. Specifically, the function of the FLEX-LL is not limited to the specific examples described above, and can also have another aspect. All embodiments can be adopted which enable improvement of the throughput, for example, by moving the wafer from the plurality of load ports to at least one of the first LLC and the second LLC; and by attaining a state in which there is no wafer in the first LLC or the second LLC, or by attaining a state in which there is only a treated wafer in the first LLC or the second LLC, by moving the wafer from one of the first LLC and the second LLC to the other.

According to one example, it is possible to add the following restriction condition to the wafer transfer conditions illustrated in each of the above-described examples.

Restriction Condition 1:

A process job which designates a transfer path of the wafer shall permit the use of both of the first LLC and the second LLC.

More specifically, a control job which is being executed or a control job which serves as a trigger for the execution of the FlexLL can add such a restriction condition that both of the LLCs need to be available. In other words, in the case where a control job with which a user intentionally designates any one of the LLC 1 and the LLC 2 is being executed or is scheduled to be executed, such designation may not be achieved due to the function of the FLEX-LL, and accordingly it is determined that the wafer transfer conditions of the FLEX-LL are not satisfied.

According to another example, the following restriction condition can be added.

Restriction Condition 2:

One control job shall not transfer wafers belonging to a plurality of load ports.

Specifically, when the FLEX-LL is used in the case where the substrate treatment apparatus handles a control job of simultaneously transferring a wafer taken in or out from a certain load port and a wafer taken in or out from another load port, a logic (computation) for the transfer becomes complicated, and accordingly the above-described restriction condition is added.

According to another example, the following restriction condition can be added.

Restriction Condition 3:

Wafers taken in and out from one load port do not exist both in the first LLC and the second LLC.

For example, when the wafers A exist in both of the first LLC and the second LLC, the logic of the FLEX-LL becomes complicated, and accordingly, in such a case, the FLEX-LL can be not executed. As a modified example of the restriction condition 3, when wafers taken in and out from one load port are scheduled to be transferred to the first LLC and the second LLC by the control job, it is acceptable that the wafers taken in and out from one load port proceed only to the first LLC or the second LLC by the FLEX-LL.

According to another example, the following restriction condition can be added.

Restriction Condition 4:

There is not such a dedicated condition that one LLC can accept only wafers taken in and out from one load port.

For example, in the case where only the wafers A can be loaded into one LLC, it is not preferable to move the wafers A to another LLC; and accordingly, this restriction condition can be added.

By the way, when wafers are moved between the LLCs, if the sum of the number of wafers to be moved in a source LLC and the number of wafers in a destination LLC is greater than 25, the movement of wafers between the LLCs cannot be completed. Then, it is acceptable that the controller executes the movement of the wafer between the LLCs, after having confirmed that such a problem does not occur.

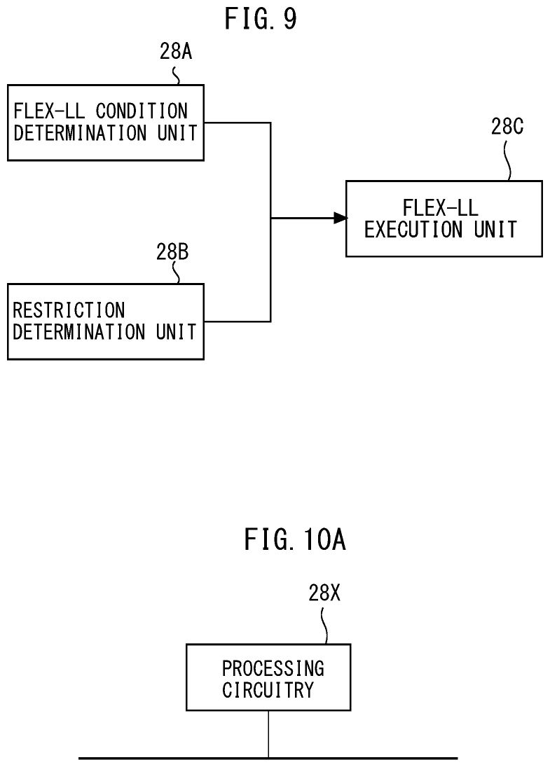

FIG. 9 is a functional block diagram of the controller. The controller 28 can include a FLEX-LL condition determination unit 28A which determines whether or not the wafer transfer conditions for executing the FLEX-LL are satisfied. Furthermore, if necessary, a restriction determination unit 28B for determining whether or not the restriction condition is satisfied can be provided. When the restriction condition is not added to the wafer transfer conditions, the restriction determination unit 28B can be omitted. When it is determined that both of the condition determination unit 28A and the optionally provided restriction determination unit 28B satisfy the conditions, the wafer is moved between the above-described LLCs by a FLEX-LL execution unit 28C.

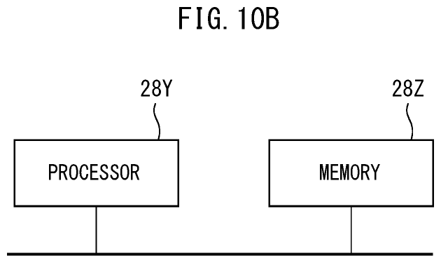

FIG. 10A illustrates a configuration example of controller 28. The controller includes processing circuitry 28X. Each of the above-mentioned functions performed by the controller 28 is realized by the processing circuitry 28X. Specifically, the processing circuitry 28X determines whether predetermined wafer transfer conditions are satisfied, and issues a command to the wafer moving device to move a wafer between the first load lock chamber and the second load lock chamber when the wafer transfer conditions are satisfied. The processing circuitry 28X may be dedicated hardware (dedicated circuitry) or a CPU (also called “central processing unit,” “processing apparatus,” “calculation apparatus,” “microprocessor,” “microcomputer,” “processor” or “DSP”) that executes a program stored in a memory. When the processing circuitry 28X is dedicated hardware, the processing circuitry 28X corresponds to a single circuit, a composite circuit, a programmed processor, a parallel programmed processor, an ASIC, an FPGA or a combination of these units. Each function of the controller may be implemented by each processing circuitry or the respective functions may be collectively implemented by the processing circuitry.

FIG. 10B illustrates a configuration example of the controller 28 when the processing circuitry is a CPU. In this case, the above-described series of processes are implemented by software, firmware or a combination of software and firmware. Software or firmware is written as a program and stored in a computer-readable memory 28Z. The flow in FIGS. 3, 4, 6 are automatically executed. The processor 28Y implements the above-described respective functions by reading and executing the program stored in the memory 28Z. In short, this program causes a computer to execute the above-described respective functions, for examples steps S1-S3, S4-S6, or S7-S10. The memory corresponds to a non-volatile or volatile semiconductor memory such as RAM, ROM, flash memory, EPROM, EEPROM, magnetic disk, flexible disk, optical disk, compact disk, mini-disk, or DVD and so on. Naturally, a part of the controller 28 may be implemented by dedicated hardware and another part may be implemented by software or firmware.

Thus, each function described above is implemented by the execution of a program stored in a memory by a processor, or by the processing of the dedicated circuitry.

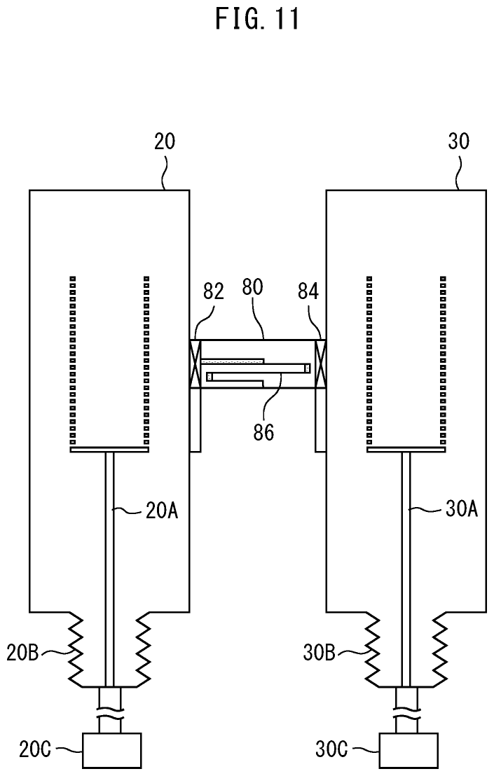

In the above-described example, the second wafer transfer device 41 is structured so as to move the wafer from one of the first LLC 20 and the second LLC 30 to the other. However, it is possible to move the wafer between the LLCs with the use of a dedicated device. FIGS. 11 to 13 illustrate examples of such dedicated wafer transfer devices.

FIG. 11 illustrates a configuration example of a wafer moving device. The wafer moving device includes an inter-load lock chamber 80, gate valves 82 and 84, and an inter-load lock wafer transfer device 86. The inter-load lock chamber 80 communicates with the first LLC 20 and the second LLC 30 via the gate valves 82 and 84, respectively. The inter-load lock wafer transfer device 86 is provided in the inter-load lock chamber 80. The inter-load lock wafer transfer device 86 is, for example, a robot for transferring the wafer. The inter-load lock wafer transfer device 86 can be provided in the inter-load lock chamber 80, in the first LLC, or in the second LLC. When the wafer is moved from one of the first LLC and the second LLC to the other by the function of the FLEX-LL, the movement is realized by the opening of the gate valves 82 and 84 and by the use of the inter-load lock wafer transfer device 86.

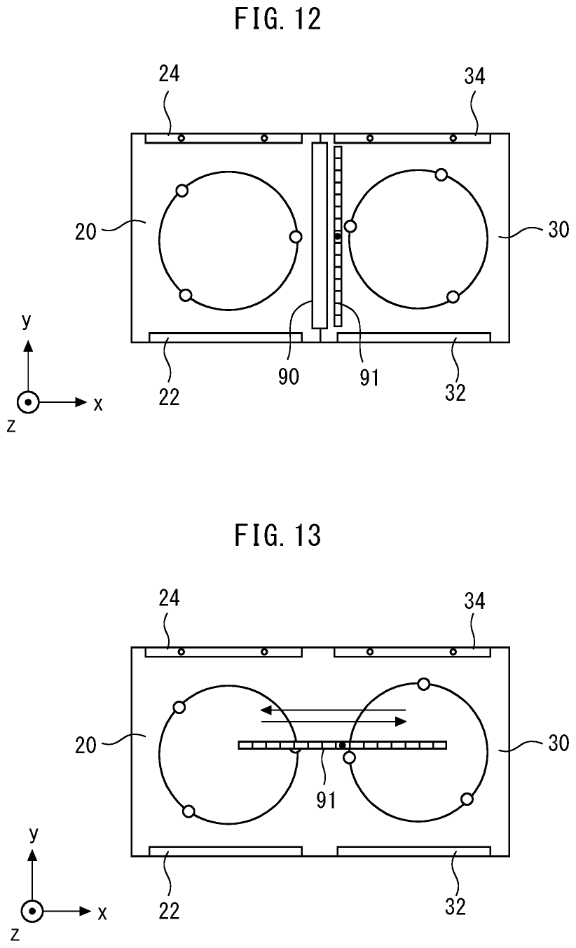

FIG. 12 illustrates a configuration example of a wafer moving device according to another example. A gate valve 90 is provided between the first LLC 20 and the second LLC 30 which are provided adjacent to each other. When the gate valve 90 is open, the first LLC 20 and the second LLC 30 are spatially connected with each other, and when the gate valve 90 is closed, the movement of gas and objects between the first LLC 20 and the second LLC 30 is intercepted. In this example, a wafer moving device 91 is provided in the second LLC 30. The wafer moving device 91 is a robot, an arm or a belt conveyor which moves a wafer from one of the first LLC 20 and the second LLC 30 to the other, when the gate valve 90 is in a open state. The wafer moving device 91 can be provided in the first LLC 20. In this example, a belt conveyor type wafer moving device 91 is illustrated.

FIG. 13 is a view for explaining a method for moving the wafer by the wafer moving device 91. When the gate valve 90 is in the open state, the wafer moving device 91 is rotated in an X-Y plane, and thereby, the wafer moving device becomes such a state as to extend long in the wafer moving direction, in other words, in the X direction. In this state, a belt of the wafer moving device 91 is driven, and thereby moves the wafer from one of the first LLC 20 and the second LLC 30 to the other.

As illustrated in FIGS. 11 to 13, due to the dedicated wafer moving device being provided, the second wafer transfer device 41 can be used for another purpose during the movement of the wafer between the LLCs, and accordingly, further improvement in throughput can be expected. In addition, the dedicated wafer moving device which has been provided makes it possible that the wafers move between the LLCs without opening of the gate valves 24 and 34.

1. A substrate treatment apparatus comprising:
a plurality of load ports;
a front-end module adjacent to the plurality of load ports;
a first load lock chamber adjacent to the front-end module, the first load lock chamber having a plurality of wafer housing slots;
a second load lock chamber adjacent to the front-end module, the second load lock chamber having a plurality of wafer housing slots;
a wafer handling chamber adjacent to the first load lock chamber and the second load lock chamber;
a first wafer transfer device in the front-end module;
a second wafer transfer device in the wafer handling chamber; and
a controller including a processor and a memory configured to cause the processor to execute a program stored in the memory, or including a dedicated circuitry, to issue a command to a wafer moving device to move a wafer between the first load lock chamber and the second load lock chamber when predetermined wafer transfer conditions are satisfied.

2. The substrate treatment apparatus according to claim 1, wherein
the wafer transfer conditions include that there is a wafer of which treatment is not completed in the first load lock chamber and the second load lock chamber, and there is a wafer to be transferred to the first load lock chamber or the second load lock chamber in any one load port of the plurality of load ports; and
the command causes the wafer moving device to operate so as to attain a state in which there is no wafer in any one of the first load lock chamber and the second load lock chamber.

3. The substrate treatment apparatus according claim 1, wherein
the plurality of load ports include a first load port, a second load port and a third load port;
the wafer transfer conditions include that there is a wafer which has been transferred from the first load port and of which treatment is not completed, in the first load lock chamber, there is a wafer which has been transferred from the second load port and of which the treatment is not completed, in the second load lock chamber, and there is a wafer to be transferred to the first load lock chamber or the second load lock chamber, in the third load port; and
the command causes the wafer moving device to operate so as to attain a state in which there is no wafer in any one of the first load lock chamber and the second load lock chamber.

4. The substrate treatment apparatus according to claim 2, wherein when the program is executed by the processor, or when the processing of the dedicated circuitry is executed, the controller issues the command to the first wafer transfer device to move the wafer from one of the plurality of load ports to a load lock chamber containing no wafer, the load lock chamber containing no wafer being one of the first load lock chamber and the second load lock chamber.

5. The substrate treatment apparatus according to claim 2, wherein the command causes the wafer moving device to operate so as to move wafers housed in the first load lock chamber or wafers housed in the second load lock chamber, the moved wafers having a smaller number than the other wafers.

6. The substrate treatment apparatus according to claim 1, wherein
the wafer transfer conditions include that a first wafer of which treatment has been completed and a second wafer of which the treatment is not completed are mixed in the first load lock chamber or the second load lock chamber; and
the command causes the wafer moving device to operate so as to attain a state in which only the first wafer exists in any one of the first load lock chamber and the second load lock chamber.

7. The substrate treatment apparatus according to claim 1, wherein
the plurality of load ports include a first load port and a second load port;
the wafer transfer conditions include that first wafers which have been transferred from the first load port and of which treatment has been completed, and second wafers which have been transferred from the second load port and of which the treatment is not completed are mixed in the first load lock chamber or the second load lock chamber; and
the command causes the wafer moving device to operate so as to attain a state in which only the first wafers exist in any one of the first load lock chamber and the second load lock chamber.

8. The substrate treatment apparatus according to claim 7, wherein the command causes the wafer moving device to operate so as to move the first wafers or the second wafers, the moved wafers having a smaller number than the other wafers.

9. The substrate treatment apparatus according to claim 1, wherein the wafer transfer conditions include that a process job which designates a transfer path of the wafer permits use of the first load lock chamber and the second load lock chamber.

10. The substrate treatment apparatus according to claim 1, wherein the wafer moving device is the second wafer transfer device.

11. The substrate treatment apparatus according to claim 1, wherein
the wafer moving device comprises:
an inter-load lock chamber configured to communicate with the first load lock chamber and the second load lock chamber via a gate valve; and
an inter-load lock wafer transfer device provided in the inter-load lock chamber, in the first load lock chamber or in the second load lock chamber.

12. The substrate treatment apparatus according to claim 1, further comprising a gate valve existing between the first load lock chamber and the second load lock chamber, the first load lock chamber and the second load lock chamber being adjacent to each other, wherein
the wafer moving device is a robot, an arm or a belt conveyor which moves the wafer from one of the first load lock chamber and the second load lock chamber to the other, when the gate valve is in a open state.

13. The substrate treatment apparatus according to claim 1, further comprising a plurality of reactor chambers in contact with the wafer handling chamber.

14. A substrate transfer method comprising:
moving a wafer from a plurality of load ports to at least one of a first load lock chamber and a second load lock chamber; and
attaining a state in which there is no wafer in the first load lock chamber or the second load lock chamber, by moving the wafer from one of the first load lock chamber and the second load lock chamber to the other, or attaining a state in which there is only a treated wafer in the first load lock chamber or the second load lock chamber by moving the wafer from one of the first load lock chamber and the second load lock chamber to the other.

15. The substrate transfer method according to claim 14, wherein
the plurality of load ports include a first load port associated with first wafers, a second load port associated with second wafers, and a third load port associated with third wafers; and
when the wafer is moved from one of the first load lock chamber and the second load lock chamber to the other, all of the first wafers, all of the second wafers, or all of the third wafers are moved.
